(19) United States
(12) Patent Application Publication
(10) Pub. No.: US 2025/0314696 A1
(43) Pub. Date: Oct. 9, 2025

(54) ELECTRONIC CIRCUIT FOR TEST OF DIGITAL CIRCUIT

(71) Applicant: STMicroelectronics International N.V., Geneva (CH)

(72) Inventor: Jean-Paul Schalck-Schmitt, Voiron (FR)

(21) Appl. No.: 19/173,311

(22) Filed: Apr. 8, 2025

(30) Foreign Application Priority Data
Apr. 9, 2024 (FR) FR2403632

(51) Int. Cl. G01R 31/317; H03K 3/037; H03K 17/687; H03K 19/20

(52) U.S. Cl. CPC G01R 31/31727; H03K 3/037; H03K 17/6872; H03K 19/20

(57) ABSTRACT

The present description concerns an electronic circuit for testing a digital signal, comprising a signal selection circuit having a first input configured to receive a signal from the digital circuit to be tested, a second input configured to receive a test mode activation signal, a third input, a first output configured to receive a state of the third input when the second input is activated and a state of the first input when the second input is deactivated, and a second output configured to receive a state of a signal present on the first input or to be set to zero when the second input is respectively activated or deactivated.

### CROSS-REFERENCE TO RELATED APPLICATIONS

This application claims the priority benefit of French patent application number FR2403632, filed on Apr. 9, 2024, entitled “Circuit électronique de test d′un circuit numérique,” which is hereby incorporated by reference to the maximum extent allowable by law.

### TECHNICAL FIELD

The present disclosure generally concerns electronic circuits for testing digital circuits.

### BACKGROUND

Electronic circuits, such as for example digital circuits, need to be able to be tested during the manufacturing or during the lifetime of the circuit. For this purpose, test circuit portions are developed jointly with the circuits to be tested (design for test).

### SUMMARY

There exists a need for a test circuit capable of testing a maximum number of signals of the associated digital circuit.

An embodiment overcomes all or part of the disadvantages of known test circuits.

An embodiment provides an electronic circuit for testing a digital signal, the electronic circuit comprising a signal selection circuit having:
a first input intended to receive a signal from a digital circuit to be tested;
a second input configured to receive a test mode activation signal;
a third input;
a first output intended to receive a state of the third input when the second input is activated and a state of the first input when the second input is deactivated; and
a second output intended to receive a state of the signal present on the first input in response to the second input being activated, and intended to be set to zero in response to the second input being deactivated.

According to an embodiment, the signal selection circuit is a multiplexer. According to an embodiment, the state of the signal present on the second output results from an AND-type logic function between the state of the test activation signal and the state of the signal present on the first input of the multiplexer.

According to an embodiment, the test circuit comprises a scan flip-flop comprising: a multiplexing stage having:
a first input coupled to the second output of the multiplexer,
a second input configured to receive the state of the shift mode activation signal,
a third input, and
an output intended to receive the state of the signal present on the first input of the multiplexing stage when its second input is in a first state and to receive the state of the signal present on the third input of the multiplexing stage when its second input is in a second state; and
a D-type flip-flop having a data input coupled to the output of the multiplexing stage.

According to an embodiment, the first output of the multiplexer is coupled to an analog block and the state of the signal on the third input of the multiplexer is held in a constant, low or high, state, at least when the test mode is activated.

According to an embodiment, the first input of the multiplexer is coupled to an output of a synchronization cell, and the third input of the multiplexer is intended to receive a reset test signal generated outside of the digital block.

According to an embodiment, the first output of the multiplexer is coupled to an output of a clock signal division block, and the third input of the multiplexer is intended to receive a clock test signal generated outside of the digital block.

According to an embodiment, the multiplexer comprises a first and a second branches each coupling a first node to a second node;
the first branch being formed of:
   two first PMOS transistors in series between the first node and a third node,
   two first NMOS transistors in series between the third node and the second node, and
   a second PMOS transistor in series with a second NMOS transistor, a conduction node of the second PMOS transistor being coupled to a conduction node common to the two first PMOS transistors, and a conduction node of the second NMOS transistor being coupled to a conduction node common to the two first NMOS transistors;
the second branch being formed of two third PMOS transistors in series between the first node and the third node, and two third NMOS transistors in series between the third node and the second node; and
the multiplexer further comprising a fourth PMOS transistor coupling the first node to a conduction node common to the second PMOS and NMOS transistors.

According to an embodiment, the multiplexer comprises a first inverter circuit configured to deliver a state inverse to the state of the test mode activation signal on:
the control node of one of the first NMOS transistors coupling the third node to the conduction node common to the first two NMOS transistors,
the control node of the second PMOS transistor, and
the control node of the third PMOS transistor which is coupled to the third node.

According to an embodiment, the multiplexer comprises a second inverter circuit coupling the conduction node, common to the second PMOS and NMOS transistors, and the second output.

According to an embodiment, the multiplexer comprises a third inverter circuit coupling the third node and the first output.

According to an embodiment, the control node of one of the first PMOS transistors having a conduction node coupled to the first node, and the control node of one of the first NMOS transistors having a conduction node coupled to the second node are intended to receive the state of the signal present on the first input of the multiplexer.

According to an embodiment,
the control node of one of the first PMOS transistors has a conduction node coupled to the third node, and
the control node of the fourth PMOS transistor, the control node of one of the third NMOS transistors coupled to the third node, and the control node of the second NMOS transistor, are intended to receive the state of the test activation signal.

According to an embodiment, the control node of one of the third PMOS transistors, having a conduction node coupled to the first node, and the control node of one of the third NMOS transistors coupled to the second node, are intended to receive the state of the signal present on the third input of the multiplexer.

According to an embodiment, the state of the signal present on the third input of the multiplexer results from a test vector generator.

According to an embodiment, the electronic test circuit and the digital circuit are arranged on a same chip.

### BRIEF DESCRIPTION OF THE DRAWINGS

The foregoing features and advantages, as well as others, will be described in detail in the rest of the disclosure of specific embodiments given as an illustration and not limitation with reference to the accompanying drawings, in which:

FIG. 1 very schematically shows in the form of blocks an example of an integrated circuit of the type to which the embodiments apply;

FIG. 2 schematically shows an example of a circuit of FIG. 1;

FIG. 3 shows an example of a circuit of FIG. 1 according to an embodiment;

FIG. 4 schematically shows a circuit of FIG. 3 according to an embodiment;

FIG. 5 schematically shows a circuit of FIG. 1 according to an embodiment;

FIG. 6 schematically shows a circuit of FIG. 1 according to an embodiment; and

FIG. 7 schematically shows a circuit of FIG. 1 according to an embodiment.

### DETAILED DESCRIPTION OF ILLUSTRATIVE EMBODIMENTS

Like features have been designated by like references in the various figures. In particular, the structural and/or functional features that are common among the various embodiments may have the same references and may dispose identical structural, dimensional and material properties.

For clarity, only those steps and elements which are useful to the understanding of the described embodiments have been shown and are described in detail.

Unless indicated otherwise, when reference is made to two elements connected together, this signifies a direct connection without any intermediate elements other than conductors, and when reference is made to two elements coupled together, this signifies that these two elements can be connected or they can be coupled via one or more other elements.

In the following description, where reference is made to absolute position qualifiers, such as “front”, “back”, “top”, “bottom”, “left”, “right”, etc., or relative position qualifiers, such as “top”, “bottom”, “upper”, “lower”, etc., or orientation qualifiers, such as “horizontal”, “vertical”, etc., reference is made unless otherwise specified to the orientation of the drawings.

Unless specified otherwise, the expressions “about”, “approximately”, “substantially”, and “in the order of” signify plus or minus 10% or 10°, preferably of plus or minus 5% or 5°.

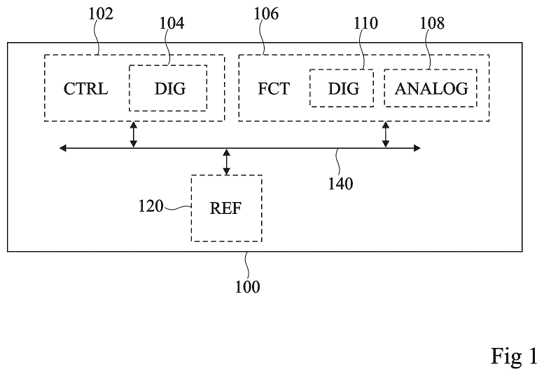

FIG. 1 very schematically shows in the form of blocks an example of an integrated circuit 100 of the type to which the embodiments apply.

Circuit 100 comprises, for example, a processing unit 102 (CTRL) comprising one or a plurality of processors, for example under control of instructions stored in an instruction memory (not shown).

Circuit 100 further comprises a module 120 (REF) having a reference clock signal generation block comprising an oscillator generating a reference frequency.

Circuit 100 may integrate other circuits implementing other functions (for example, one or a plurality of volatile and/or non-volatile memories, other processing units, an input/output interface I/O), symbolized by a block 106 (FCT) in FIG. 1.

Blocks 102, 106, and 120 are for example coupled to one another and/or to the rest of integrated circuit 100 via a bus 140 conveying the required signals.

Module 106 or blocks 102 and/or 120 further comprise for example other functional blocks.

Blocks 102, 106 and/or block 120 for example comprise one or a plurality of digital circuits shown in the form of blocks 104, 110 (DIG). Block 106, or each of blocks 102, 106, 120, for example also comprise parts 108 (ANALOG) dedicated to an analog operation and which are, for example, in communication with the respective digital blocks.

There exists a need to test digital circuits 104, 110 be it during the manufacturing or during the lifetime of circuit 100. Defects or faults or errors may be tested if there exists a well-specified procedure for exposing it in real silicon. For this purpose, test circuits are designed and, for example, integrated in circuit 100 to test signals of circuits 104, 110. This enables to observe internal nodes so that the embedded functions can also be tested.

Detectable defects or faults are, for example, the sticking of a signal to a given value (0 or 1), a logic error, or also a clock frequency error.

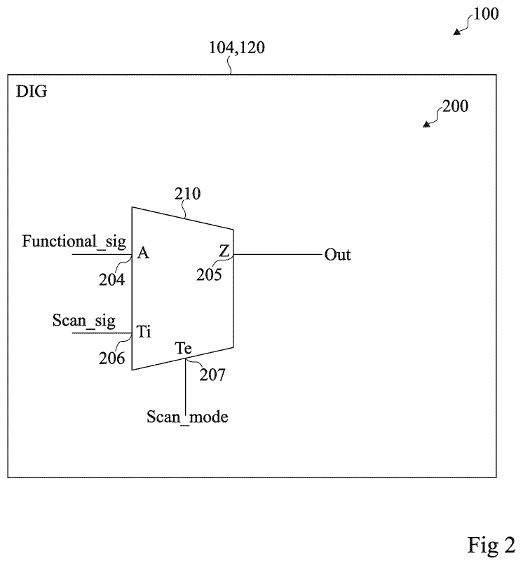

FIG. 2 very schematically shows an example of a circuit 210 of FIG. 1.

More specifically, circuit 210 is a signal selection circuit, in particular a multiplexer forming part of a test circuit 200 of one of digital circuits 104, 110.

In the shown example, multiplexer 210 is placed in series on a path to be tested of digital circuit 104, 110 so as to receive on an input a signal to be tested (Functional_sig) and to have an output Z, 205 coupled to the rest of the digital circuit 104, 110.

Multiplexer 210 comprises a first input A, 204 which is placed in circuit 104, 110 to receive a state of a signal Functional_sig from the digital circuit to be tested.

Multiplexer 210 further comprises a second input Te, 207, intended to receive the state of a signal Scan_mode which, according to its value, activates or deactivates the switching of circuit 104, 110 to a test mode.

Multiplexer 210 further comprises a third input Ti, 206 configured to receive a state of a test signal Scan_sig. In other words, signal Scan_sig will replace test signal Functional_sig when the second input is activated by signal Scan_mode. signal Scan_sig may take different forms according to the nature of the signal Functional_sig to be tested.

Output Z, 205 is configured to receive the state of signal Scan_sig when the second input Te is activated, and a state of the signal Functional_sig of the first input A, 204 when the second input Te is deactivated. The signal Out on output Z, 205 then propagates to the rest of the digital circuit.

In the text, an activated input means that it receives a signal in the high state (or 1) and a deactivated input means that it receives a signal in the low state (or 0). It is however possible to implement an inverse solution.

Signal Out then flows into the rest of the digital circuit, and its state can be stored in a flip-flop to enable its observation during the test. To be able to observe the effect of the replacing of signal Functional_sig by signal Signal_sig, the flip-flops which form part of circuit 104, 110 are of a type different from standard flip-flops. These flip-flops, called scanned, may be placed in a test mode or scan mode when signal Scan_mode is high, for example, so that the state of the signal that they have stored can be observed on their output during a subsequent clock signal pulse. In test mode, all the flip-flops that can be tested are placed in series, the output of a flip-flop being coupled or connected to a test input (Ti) of the next one, so as to form a shift register. By injecting an appropriate test vector (that is, a series of 0s or 1s, each separated by a clock pulse) into the chain formed by the flip-flops in series during the test mode, it is thus possible to test whether faults are present on different portions of the circuit. These test vectors may for example be calculated by using an automatic test pattern generator.

When the test begins, signal Scan_mode for example switches to the high state and signal Scan_sig is present on output Z, 205. Thereby, it is possible to test the rest of the circuit connected to output Z, for example, by simulating the expected signal Out with signal Scan_sig, or by setting this signal to a given value.

However, signal Functional_sig can then no longer be observed. As a result, the test coverage becomes in this case limited to less than 70% for multiplexer 210. The aim of the test designs being to achieve a test coverage close to or higher than 99%, it is necessary to envisage a solution to increase this test coverage and, in particular, to enable the observation of input A, 204 during the test mode.

A solution could consist in using an additional second multiplexer, similar to the first one, but with the input A of the first multiplexer coupled, preferably connected, to the input Ti of the second multiplexer and the input Ti of the first multiplexer coupled, preferably connected, to input A of the second multiplexer. This would enable to obtain an observability of the state of the signal of input A, 204 of the first multiplexer through output Z of the second multiplexer.

However, such a solution requires an increase in the number of transistors implemented for the testing, as well as an increase in the chip surface area and power consumption. In an example, twenty-four transistors are necessary to implement two multiplexers 210.

Further, in this solution, although it increases the test coverage, for example to approximately 80% for the two multiplexers, it does not enable to achieve the near 99% coverage which is targeted.

To overcome these problems, the embodiments provide for the electronic test circuit 200 of digital circuit 104, 110 to comprise a multiplexer having:
the first input A intended to receive a signal from the digital circuit to be tested;
the second input Te configured to receive a test activation signal;
the third input Ti;
the first output Z intended to receive a state of the third input Ti when the second input Te is activated and a state of the first input A when the second input Te is deactivated; and
a second output NSZ intended to receive a state of the signal present on the first input A or to be set to zero when the second input Te is respectively activated or deactivated.

The state of the signal on the first input A being accessible on the new output NSZ when the test mode is activated, that is, when the second input Te is activated, the test coverage rate is thus increased.

This enables to limit the consumed chip surface area as compared with a solution with two multiplexers 210, while increasing the test coverage to more than 99% and while limiting the power consumption.

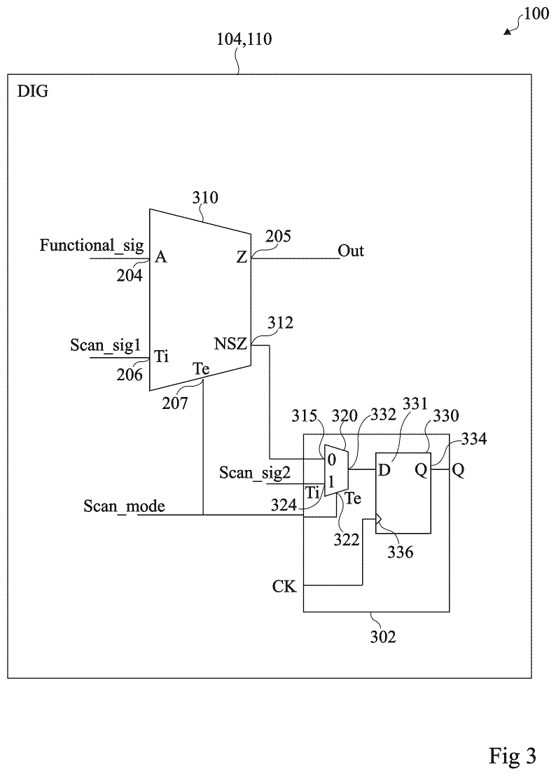

FIG. 3 shows an example of a circuit of FIG. 1 according to an embodiment.

More particularly, FIG. 3 shows a portion of the test circuit 200 of digital circuit 104, 110.

In the shown example, test circuit 200 comprises signal selection circuit 310, in particular a multiplexer. Multiplexer 310 is similar to multiplexer 210 except that it comprises an additional output NSZ, 312.

Output NSZ, 312 is configured to, on the one hand, receive a state of the signal Functional_sig present on the first input A, 204 when the second input Te is activated, and to be set to zero when the second input Te is deactivated.

In an example, the state of the signal present at the second output NSZ, 312 results from an AND-type logic function between the state of the signal Scan_mode present at input Te, 207 and the state of the signal present at the first input A, 204 of multiplexer 310.

To be able to observe the state of the signal on the second output NSZ, 312, the latter is coupled, preferably connected, to a flip-flop 302 which can be switched to a test mode. In the rest of the text, the flip-flops that can be implemented in a test mode are referred to as scan flip-flops.

In the shown example, scan flip-flop 302 comprises a multiplexing stage 320, in other words a multiplexer 320, having a first input 315 configured to receive the state of the signal present on the second output NSZ, 312 of multiplexer 310. Multiplexing stage 320 also comprises an input Te, 322 configured to receive the state of the shift signal during the scan test. Multiplexing stage 320 further comprises another input 324 intended to receive the state of a signal Scan_sig2.

Multiplexing stage 320 further comprises an output 332 configured to receive the state of the signal present at the input 315 of multiplexing stage 320 when its second input 322 is in a first state, for example deactivated, and to receive the state of the signal present at the input 324 of multiplexing stage 320 when its second input 322 is in a second state, for example activated. The first state and the second state may be inverted according to needs.

In the shown example, scan flip-flop 302 further comprises a D-type flip-flop 330, having a data input D, 331 coupled, preferably connected, to the output 332 of multiplexing stage 320, a clock input CP, 336 is configured to receive a clock signal CK, and an output Q, 334 is configured to receive and hold the state of the D input until the next clock pulse of signal CK. The information of signal functional_sig can thus also be observed at the output 334 of flip-flop 330 when test mode is in progress.

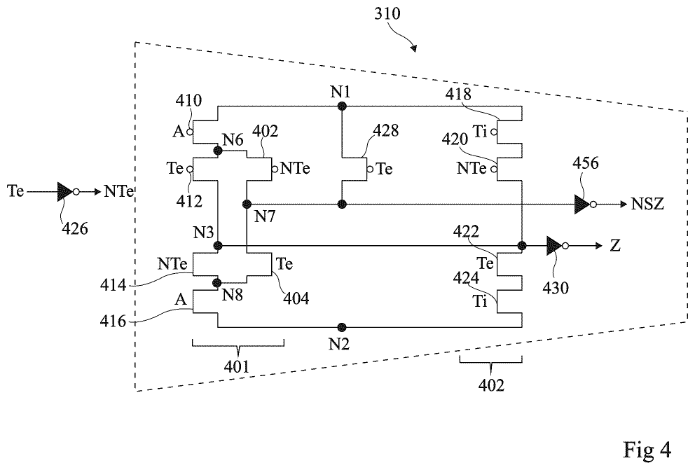

FIG. 4 schematically shows a circuit of FIG. 3 according to an embodiment. More particularly, FIG. 4 shows an embodiment of multiplexer 310.

In the shown example, multiplexer 310 comprises a first branch and a second branch 401, 402, each coupling a first node N1 to a second node N2.

The first branch 401 consists of two first PMOS transistors 410, 412 in series between the first node N1 and a third node N3. It also comprises two first NMOS transistors 414, 416 in series between the third node N3 and the second node N2. The first branch 401 further comprises a second PMOS transistor 402 in series with a second NMOS transistor 404. A conduction node of the second PMOS transistor 402 is coupled to a conduction node N6 common to the first two PMOS transistors 410, 412. A conduction node of the second NMOS transistor 404 is coupled to a conduction node N8 common to the two first NMOS transistors 414, 416.

The second branch 402 is formed of two third PMOS transistors 418, 420 in series between the first node N1 and the third node N3, and two third NMOS transistors 422, 424 in series between the third node N3 and the second node N2.

Multiplexer 310 further comprises a fourth PMOS transistor 428 coupling the first node N1 to a conduction node N7 common to the second PMOS and NMOS transistors 402, 404.

The state of the signal on input A is present on the control nodes of transistors 410 and 416.

The state of the signal on input Te is present on the control nodes of transistors 404, 412, 422, and 428.

The state of the signal on input Ti is present on the control nodes of transistors 418 and 424.

Circuit 200 for example comprises an inverter 426 configured to provide the state NTe inverse to signal Scan_mode on the control nodes of transistors 414, 420, and 402. In an example, inverter 426 is integrated to multiplexer 310.

In the shown example, multiplexer 310 further comprises an inverter 430 configured to provide the state inverse to the signal present on the third node N3 to output Z, 205.

In the shown example, multiplexer 310 further comprises an inverter circuit 456 coupling conduction node N7, common to the second PMOS and NMOS transistors 402, 404, and the second output NSZ.

As described in the example of FIG. 2, in the test mode, all the flip-flops, including flip-flop 302, are placed in series, in the scan shift mode, the output of a flip-flop being coupled or connected to a test input Ti of the next one, so as to form a shift register.

The multiplexer of FIG. 4 comprises seventeen transistors, which is much lower than the number of transistors necessary in the solution with two multiplexers.

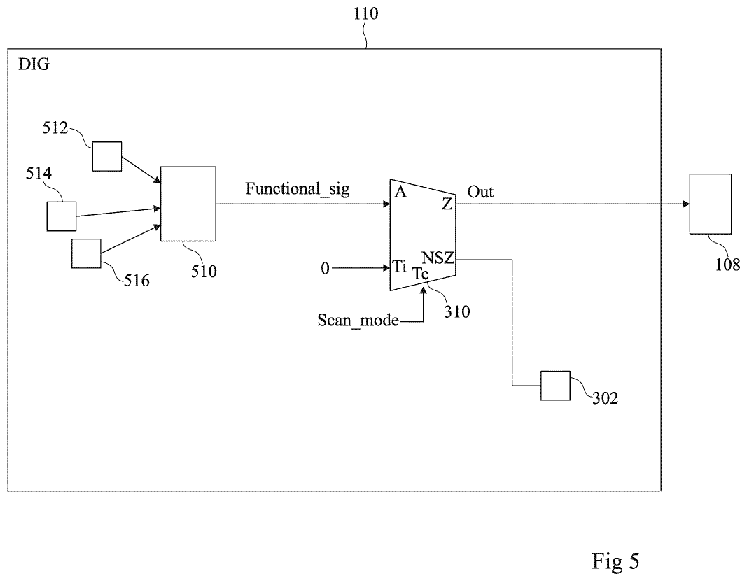

FIG. 5 schematically shows a circuit of FIG. 1 according to an embodiment. More particularly, FIG. 5 shows an example of multiplexer 310.

In the shown example, digital circuit 110 is coupled, preferably connected, to analog circuit 108.

In this case, in order to protect circuit 108 during the test mode, input Ti, 206 receives signal Scan_sig at a given level, for example 0. This 0 level is present on output Z, and circuit 108 is thus protected.

In the example of FIG. 5, signal Functional_sig for example originates from a combinational logic block coupled, preferably connected, at its input to, for example, three flip-flops 512, 514, and 516.

When the test mode is activated, signal Functional_sig can be observed on scan flip-flop 302.

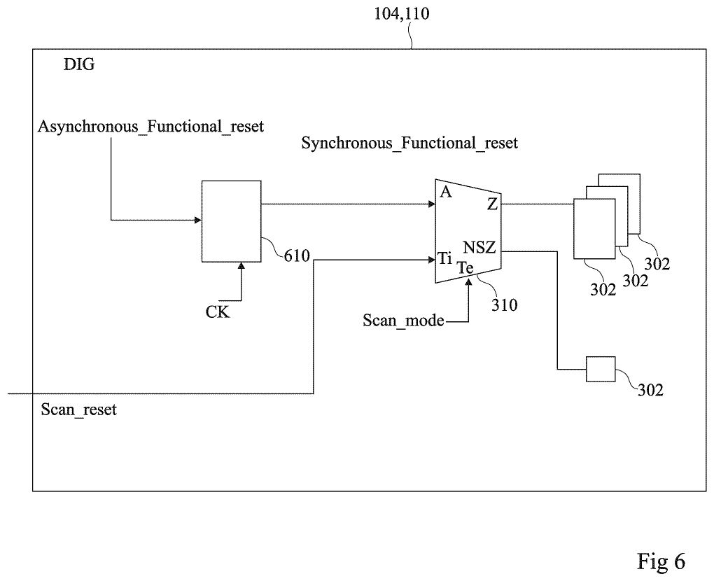

FIG. 6 schematically shows a circuit of FIG. 1 according to an embodiment. More particularly, FIG. 6 shows another example of implementation of multiplexer 310.

In the shown example, the signal received on input A, 204 originates from a reset signal resynchronization cell 610.

This resynchronization cell is for example formed of two or more D flip-flops in series and having their reset inputs connected together and receiving a reset signal that can be desynchronized Asynchronous_Functional_reset. At the output of this cell 610, reset signal Synchronous_Functional_reset is resynchronized to be distributed to one or a plurality of flip-flops similar to scan flip-flop 302. In this example, signal Synchronous_Functional_reset is, in this example, signal Functional_sig. Input A, 204 of multiplexer 310 receives reset signal Synchronous_Functional_reset.

When the test mode is activated, a reset signal Scan_reset, similar to that provided by a synchronized power-on reset cell, is for example generated by a block external to block 104, 110, and sent to input Ti, 206. Signal Scan_sig is, in this example, signal Scan_reset. The state of signal Scan_reset is present on output Z and is distributed to the other flip-flops 302 of circuit 104, 110. The state of signal Synchronous_Functional_reset is present on the second output NSZ and can be observed on the respective scan flip-flop 302.

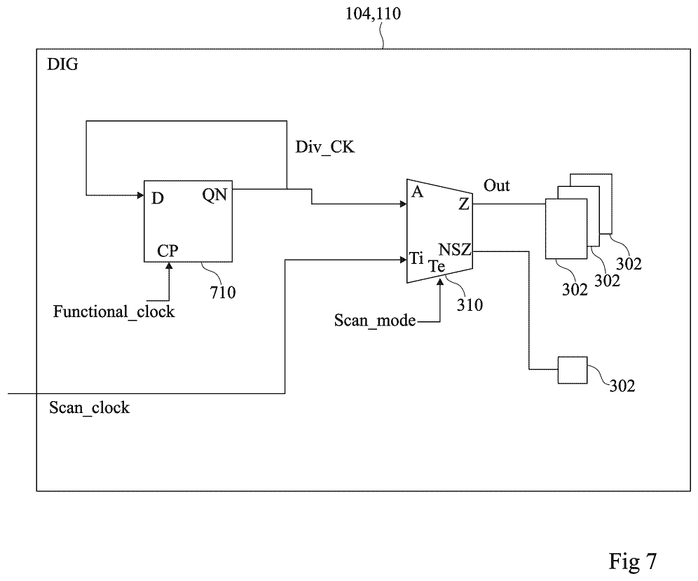

FIG. 7 schematically shows a circuit of FIG. 1 according to an embodiment.

More particularly, FIG. 7 shows another example of implementation of multiplexer 310.

In the shown example, the signal Div_CK received on input A, 204 originates from a clock signal frequency division block 710. Signal Div_CK is, in this example, signal Functional_sig. Block 710 is for example formed of one or a plurality of D flip-flops. A clock signal Functional_clock is injected to the clock input CP of the flip-flop of block 710, and the QN output of the flip-flop is coupled to the D data input of block 710. At the output of block 710, clock signal Functional_clock becomes signal Div_CK having a frequency divided with respect to that of signal Functional_CK.

The input Ti, 206 of multiplexer 310 receives a signal Scan_clock generated, for example, outside block 104, 110, and which allows the testing of the flip-flop logic. Signal Scan_sig is, in this example, signal Scan_clock.

When the test mode is activated, by the setting to the high state of signal Scan_mode for example, the state of signal Div_CK becomes observable on the flip-flop 302 coupled to the second input NSZ of multiplexer 310. In other words, output NSZ, in this case, provides observability on the clock pin.

In this test mode, signal Scan_clock is present on output Z and may be distributed throughout the rest of circuit 104, 110, for example to other scan-type flip-flops 302.

Various embodiments and variants have been described. The person skilled in the art will understand that certain features of these various embodiments and variants could be combined, and other variants will become apparent to the person skilled in the art, in particular multiplexer 310 may comprise other outputs than outputs Z and NSZ, if these outputs allow the observation of signals that escape the test coverage.

Finally, the practical implementation of the described embodiments and variants is within the abilities of those skilled in the art, based on the functional indications given above. In particular, the flip-flops 302 used in blocks 104, 110 may have an architecture different from that provided in FIG. 3, as long as they are configured to select a signal from among a signal of Scan_sig type and a signal of Functional_sig type, according to the activation or to the deactivation of the test mode.

What is claimed is:

1. An electronic circuit for testing a digital signal, the electronic circuit comprising:
a signal selection circuit having:
a first input configured to receive a signal from a digital circuit to be tested;
a second input configured to receive a test mode activation signal;
a third input;
a first output configured to receive a state of the third input when the second input is activated and a state of the first input when the second input is deactivated; and
a second output configured to receive a state of the signal present on the first input in response to the second input being activated, and configured to be set to zero in response to the second input being deactivated.

2. The electronic circuit according to claim 1, wherein a state of a signal present on the second output results from an AND-type logic function between a state of the test mode activation signal and the state of the signal present on the first input of the signal selection circuit.

3. The electronic circuit according to claim 1, further comprising:
a scan flip-flop comprising:
a multiplexing stage having:
a first input connected to the second output of the signal selection circuit;
a second input configured to receive a state of the test mode activation signal;
a third input; and
an output configured to receive a state of the signal present on the first input of the multiplexing stage when its second input is in a first state and to receive a state of a signal present on the third input of the multiplexing stage when its second input is in a second state; and
a D-type flip-flop having a data input coupled to the output of the multiplexing stage.

4. The electronic circuit according to claim 1, wherein the first output of the signal selection circuit is coupled to an analog block, and a state of a signal on the third input of the signal selection circuit is held in a low state at least when a test mode is activated.

5. The electronic circuit according to claim 1, wherein the first input of the signal selection circuit is coupled to an output of a synchronization cell, and the third input of the signal selection circuit is configured to receive a reset test signal generated outside of a digital block.

6. The electronic circuit according to claim 1, wherein the first output of the signal selection circuit is coupled to an output of a clock signal division block, and the third input of the signal selection circuit is configured to receive a clock test signal generated outside of a digital block.

7. The electronic circuit according to claim 1, wherein the signal selection circuit comprises first and second branches, each coupling a first node to a second node;
the first branch comprising:
two first P-type metal-oxide-silicon (PMOS) transistors in series between the first node and a third node;
two first N-type metal-oxide-silicon (NMOS) transistors in series between the third node and the second node; and
a second PMOS transistor in series with a second NMOS transistor, a conduction node of the second PMOS transistor being coupled to a conduction node common to the two first PMOS transistors, and a conduction node of the second NMOS transistor being coupled to a conduction node common to the two first NMOS transistors;
the second branch comprising two third PMOS transistors in series between the first node and the third node, and two third NMOS transistors in series between the third node and the second node; and
the signal selection circuit further comprising a fourth PMOS transistor coupling the first node to a conduction node common to the second PMOS and NMOS transistors.

8. The electronic circuit according to claim 7, wherein the signal selection circuit comprises a first inverter circuit configured to deliver a state inverse to the state of the test mode activation signal on:
a control node of one of the first NMOS transistors coupling the third node to the conduction node common to the two first NMOS transistors,
a control node of the second PMOS transistor, and
a control node of one of the third PMOS transistors that is coupled to the third node.

9. The electronic circuit according to claim 8, wherein the signal selection circuit comprises a second inverter circuit coupling the conduction node, common to the second PMOS and NMOS transistors, and the second output.

10. The electronic circuit according to claim 9, wherein the signal selection circuit comprises a third inverter circuit coupling the third node and the first output.

11. The electronic circuit according to claim 7, wherein a control node of one of the first PMOS transistors having a conduction node coupled to the first node and a control node of one of the first NMOS transistors having a conduction node coupled to the second node are configured to receive the state of the signal present on the first input of the signal selection circuit.

12. The electronic circuit according to claim 7, wherein:
a control node of one of the first PMOS transistors having a conduction node coupled to the third node, a control node of the fourth PMOS transistor, a control node of one of the third NMOS transistors coupled to the third node, and a control node of the second NMOS transistor, are configured to receive the state of the test mode activation signal.

13. The electronic circuit according to claim 7, wherein a control node of one of the third PMOS transistors, having a conduction node coupled to the first node, and a control node of one of the third NMOS transistors, coupled to the second node, are configured to receive a state of a signal present on the third input of the signal selection circuit.

14. The electronic circuit according to claim 1, wherein a state of a signal present on the third input of the signal selection circuit originates from a test vector generator.

15. The electronic circuit according to claim 1, wherein the electronic circuit and the digital circuit are arranged on a same chip.

16. An electronic circuit for testing a digital signal, the electronic circuit comprising:
a signal selection circuit having:
a first input configured to receive a signal from a digital circuit to be tested;
a second input configured to receive a test mode activation signal;
a third input;
a first output configured to receive a state of the third input when the second input is activated and a state of the first input when the second input is deactivated; and
a second output configured to receive a state of the signal present on the first input in response to the second input being activated, and configured to be set to zero in response to the second input being deactivated; and
a scan flip-flop comprising:
a multiplexing stage having a first input connected to the second output of the signal selection circuit, a second input configured to receive a state of the test mode activation signal, and a third input; and
a D-type flip-flop having a data input coupled to an output of the multiplexing stage.

17. The electronic circuit according to claim 16, wherein the signal selection circuit comprises first and second branches, each coupling a first node to a second node;
the first branch comprising:
two first P-type metal-oxide-silicon (PMOS) transistors in series between the first node and a third node;
two first N-type metal-oxide-silicon (NMOS) transistors in series between the third node and the second node; and
a second PMOS transistor in series with a second NMOS transistor, a conduction node of the second PMOS transistor being coupled to a conduction node common to the two first PMOS transistors, and a conduction node of the second NMOS transistor being coupled to a conduction node common to the two first NMOS transistors;
the second branch comprising two third PMOS transistors in series between the first node and the third node, and two third NMOS transistors in series between the third node and the second node; and
the signal selection circuit further comprising a fourth PMOS transistor coupling the first node to a conduction node common to the second PMOS and NMOS transistors.

18. The electronic circuit according to claim 16, wherein the first output of the signal selection circuit is coupled to an analog block, and a state of a signal on the third input of the signal selection circuit is held in a low state at least when a test mode is activated.

19. The electronic circuit according to claim 16, wherein the first input of the signal selection circuit is coupled to an output of a synchronization cell, and the third input of the signal selection circuit is configured to receive a reset test signal generated outside of a digital block.

20. The electronic circuit according to claim 16, wherein the first output of the signal selection circuit is coupled to an output of a clock signal division block, and the third input of the signal selection circuit is configured to receive a clock test signal generated outside of a digital block.
